(19) United States
(12) Patent Application Publication
(10) Pub. No.: US 2026/0075710 A1
(43) Pub. Date: Mar. 12, 2026

(54) FABRICATION PROCESS AND SYSTEM FOR COPPER INTERCONNECTS

(71) Applicants: BAE Systems Information and Electronic Systems Integration Inc., Nashua, NH (US); UNIVERSITY OF MASSACHUSETTS, Westborough, MA (US)

(72) Inventors: Ian P. Armstrong, Concord, NH (US); Alkim Akyurtlu, Lowell, MA (US); Guinevere Marie Strack, Hudson, NH (US)

(73) Assignees: BAE Systems Information and Electronic Systems Integration Inc., Nashua, NH (US); UNIVERSITY OF MASSACHUSETTS, Westborough, MA (US)

(21) Appl. No.: 18/830,229

(22) Filed: Sep. 10, 2024

(51) Int. Cl. H05K 1/09; B22F 10/10; B22F 10/50; B33Y 10/00; B33Y 40/20; B33Y 80/00; H01L 21/48; H05K 3/12

(52) U.S. Cl. CPC H05K 1/097; B22F 10/10; B22F 10/50; B33Y 10/00; B33Y 40/20; B33Y 80/00; H05K 3/125; B22F 2301/10; H10W 70/098

(57) ABSTRACT

Additive manufacturing techniques are described. In one example, a method includes printing, using a printable copper ink, a layer of copper onto a substrate, applying a photonic sintering process to cure the layer of copper to produce a cured layer of copper, repeating, in an alternating manner, the printing and the photonic sintering process to individually print and cure a plurality of additional layers of copper over the cured layer of copper to produce a copper pillar having a selected height, and after forming the copper pillar to the selected height, depositing, onto the substrate, a dielectric material at least partially surrounding the copper pillar.

### FIELD OF DISCLOSURE

The present disclosure relates to additive manufacturing and, more particularly, to systems and processes for producing copper interconnects using additive manufacturing.

### BACKGROUND

Conductive interconnects, commonly referred to as vias, are widely used to electrically connect components on different layers or surfaces of a multi-layered electrical circuit structure, such as a printed circuit board or microelectronics package. Copper vias and pillars for microelectronics packaging can be fabricated using laser or mechanical drilling; however these processes can be time intensive and may involve large equipment/infrastructure.

### SUMMARY

Aspects and embodiments are directed to techniques for producing copper interconnects using additive manufacturing processes.

According to one example, a method comprises: printing, using a printable copper ink, a layer of copper onto a substrate; applying a photonic sintering process to cure the layer of copper to produce a cured layer of copper; repeating, in an alternating manner, the printing and the photonic sintering process to individually print and cure a plurality of additional layers of copper over the cured layer of copper to produce a copper pillar having a selected height; and after forming the copper pillar to the selected height, depositing, onto the substrate, a dielectric material at least partially surrounding the copper pillar.

According to another example, method comprises: printing, using a printable copper ink, a plurality of layers of copper onto a substrate, individual layers of copper being stacked on top of one another to produce a copper pillar having a selected height; after printing each individual layer of copper, and prior to printing a subsequent layer of copper, curing the individual layer of copper, such that the plurality of layers of copper are individually printed and cured in sequence; and after forming the copper pillar to the selected height, depositing, onto the substrate, a dielectric material at least partially surrounding the copper pillar.

Another example is directed to a computer program product comprising one or more non-transitory machine-readable mediums having instructions encoded thereon that when executed by at least one processor cause a process to be carried out for producing a copper interconnect using additive manufacturing. The process comprises: controlling a printing apparatus to print, using a printable copper ink, a layer of copper onto a substrate; controlling a curing apparatus to cure the layer of copper; repeating, in an alternating manner, the acts of controlling the printing apparatus to print the layer of copper and controlling the curing apparatus to cure the layer of copper to individually print and cure a plurality of additional layers of copper over the layer of copper to produce a copper pillar having a selected height. After the copper pillar is formed to the selected height, the process may further comprise controlling the printing apparatus to print, onto the substrate, a dielectric material at least partially surrounding the copper pillar.

Still other aspects, embodiments, and advantages of these examples are described in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

In the figures:

FIG. 1 is a block diagram of a system for fabricating copper interconnects, according to aspects of the present disclosure;

FIG. 2 is a flow diagram of one example of a process for fabricating copper interconnects, according to aspects of the present disclosure;

FIGS. 3A-F are diagrams illustrating example formation stages of a copper interconnect produced on a substrate using the process of FIG. 2, according to aspects of the present disclosure; and

FIG. 4 is a block diagram of one example of a computing system that can be used to implement one or more components of the system of FIG. 1, according to aspects of the present disclosure.

Although the following detailed description will proceed with reference being made to illustrative embodiments, many alternatives, modifications, and variations thereof will be apparent in light of this disclosure.

### DETAILED DESCRIPTION

Techniques are disclosed herein for fabricating copper interconnects, also referred to as pillars or vias, on a substrate, such as a printed circuit board, for example, using additive manufacturing processes. As described in more detail below, certain examples implement a combination of aerosol jet printing of copper and dielectrics and the use of photonic sintering to cure the copper to make a conductive structure. This approach is in contrast to other techniques for fabricating conductive interconnects that involve drilling and plating processes or use thermal curing of silver inks.

According to certain examples, a method includes printing, using a printable copper ink, a layer of copper onto a substrate, and applying a photonic sintering process to cure the layer of copper. The method may further include repeating, in an alternating manner, the printing and the photonic sintering process to individually print and cure a plurality of additional layers of copper over the layer of copper to produce a copper pillar having a selected height. After forming the copper pillar to the selected height, the method may include depositing, onto the substrate, a dielectric material at least partially surrounding the copper pillar.

These and other features of processes for are described in more detail below.

### General Overview

Vias provide structures for interconnecting layers within a package. Production of copper vias and/or pillars for microelectronics packaging, particularly where a fine pitch (spacing) between vias is needed, can be done through the use of subtractive processes such as laser or mechanical drilling. For example, a drilling tool (laser or other) can be used to drill small holes in an existing dielectric substrate. These holes can then be filled with copper (or another conductive material) using a plating process. However, these processes can be relatively time intensive. Furthermore, due to the tendency of copper to oxidize fairly quick, the plating process may need additional steps to chemically remove oxide layers formed on the copper metal. In addition, although column structures with high aspect ratios can be deposited and thermally cured when using materials for which oxide layers do not form quickly (e.g., silver), the tendency of copper to oxidize rapidly creates challenges when attempting to apply such processes to copper structures. Thus, non-trivial issues remain with respect to producing copper interconnects using additive manufacturing.

Aspects and examples described herein provide techniques by which copper interconnect structures can be produced for microelectronics packaging and/or other applications using a fully additive process. As described in more detail below, certain examples use an alternating print-sinter process to produce copper interconnect structures layer-by-layer. For example, a printing apparatus, such as an aerosol jet printer or other 3D printing device, can be used to selectively deposit copper nanoparticle ink in one or more specific locations on a substrate. After each layer of copper ink is deposited, a photonic sintering apparatus can be used to cure the copper ink before another layer is deposited. The printing and curing processes can be repeated for each layer until the copper pillar is fully formed to a desired height. Once the copper pillar is formed, it can be encased in dielectric, which may also be deposited using the printing apparatus. In some examples, multiple copper interconnects can be formed, layer-by-layer, at the same time or during the same process, at different positions/locations on a given substrate or printed circuit board. The alternating print-sinter process can be performed, for example, in a single apparatus or station or multiple stations closely situated. Oven-based thermal cure processes may need to be ramped up over time (to reach curing temperature), and therefore can take a relatively long time, which allows oxide layers to form on the cured copper. In contrast, by using a photonic sintering process, the curing can be performed almost instantaneously and at very high temperatures, such that undesired oxidation can be avoided or otherwise reduced.

Examples may advantageously provide a process for relatively rapid fabrication of copper interconnects for multi-layer packaging without the need for subtractive processes such as laser ablation or mechanical drilling. Furthermore, the process may be performed at ambient temperatures in a normal environment rather than in an inert gas environment. In addition, examples of the process and may be used to form (and are compatible with) other printed structures, such as printed antennas, as well as passive devices and other electric circuit components and packaging. As described further below, copper vias with variety of different diameters, heights, and/or aspect ratios can be produced, such that the processes described herein can be applicable for a wide variety of circuit layouts and structures.

### Example Device Architecture

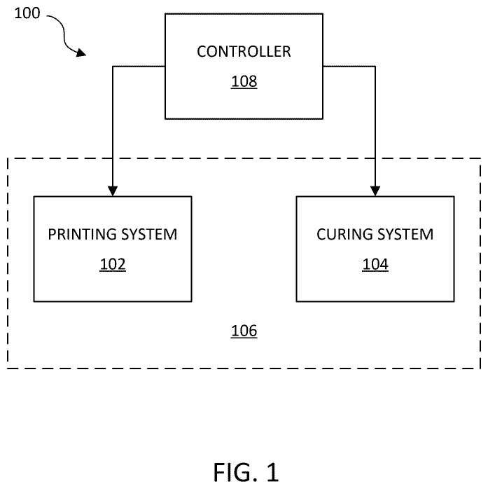

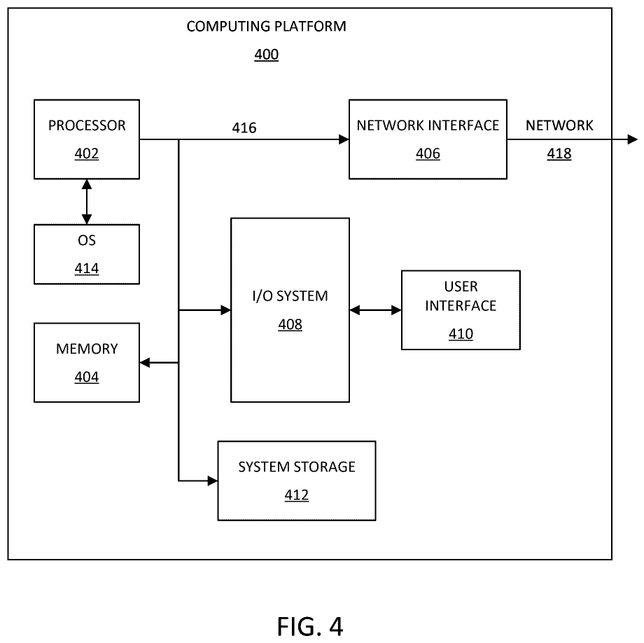

Referring to FIG. 1, there is illustrated a block diagram of a system 100 that can be used to produce copper vias according to certain examples. The system 100 includes a printing system 102 and a curing system 104. In some examples, the printing system 102 and the curing system 104 are separate devices/machines; however, in other examples, the printing system 102 and the curing system 104 may be combined in a single apparatus 106. In such instances, the apparatus may include one or more printing sub-systems (e.g., printing heads/nozzles and associated equipment) and one or more curing sub-systems. The apparatus may further include a transfer mechanism to move a device under manufacture between the printing sub-system and the curing subsystem, or to move at least the printing nozzle(s) and at least some components of the curing sub-system respectively, into and out of position to act on the device under manufacture. While the following description may refer individually to the printing system 102 and the curing system 104, it will be appreciated that in some examples, these may be components or functional elements of the combined apparatus 106. In some examples, the printing system 102 and the curing system 104 are operated under the control of a controller 108. The controller 108 may be a shared controller that controls operation of both the printing system 102 and the curing system 104, or may represent two or more individual control devices that control operation or various functionalities of the printing system 102 and/or the curing system 104. The controller 108 may be implemented in whole or in part by one or more computing platforms, such as the computing platform 400 described below with reference to FIG. 4. The controller 108 may include a user interface to allow a user to program or control one or more operating parameters of the printing system 102 and/or the curing system 104.

In some examples, the printing system 102 includes a 3D printer that can be configured to print structures using one or more types of conductive inks (e.g., copper inks) and dielectric inks. In some examples, the printing system 102 includes an aerosol jet printer. Aerosol jet printers provide a non-contact method by which to print fine features using different materials on a variety of surfaces. An aerosol jet printing process uses printable inks based on solutions or nanoparticle suspensions and can include metals and/or alloys, among other materials. In other examples, the printing system 102 may be configured to print structures using a printing process other than aerosol jet printing. For example, the printing system 102 may include a microdispenser or syringe dispenser.

To form copper interconnects, the printing system 102 may be configured to deposit thin layers of copper using a printable copper ink. In some examples, the printable copper ink has a formulation (e.g., chemical and physical formulation) that allows the ink to be printable by the printing process implemented by the printing system 102 and to be curable after printing by a curing process implemented by the curing system 104. For example, for use in aerosol jet printing, and optionally other deposition processes, the printable copper ink may include copper nanoparticles dispersed in a carrier fluid, such as in one or more carrier solvents. In some examples, two solvents are used, one that is fast evaporating and one that is slow evaporating. However, in other examples, the copper ink may include a single solvent or more than two solvents. In some examples, the solvents are polar organic solvents. The copper nanoparticles may have a size in a range of a few nanometers to a few hundred nanometers or a few micrometers. For example, the copper nanoparticles may have a diameter in a range of about (e.g., ±5% or ±10%) 2 nanometers to 500 nanometers, or about 2 nanometers to 200 nanometers. In some examples, the copper nanoparticles are individually surrounded by a thin organic layer to prevent oxidation. The copper ink may be formulated with a viscosity suitable for printing, such that the ink does not flow after deposition to such a degree as to degrade the desired shape of the printed structure. In some examples, the viscosity of the copper ink is in a range of about 1 to 2000 centipoise or 1 - 1000 centipoise.

As described above, in some examples, the printing system 102 is configured to print the copper interconnects by printing thin layers of copper ink, one layer at a time. Each layer is then cured by a curing process performed by the curing system 104 before the next layer of copper ink is printed on top of the preceding layer. The thickness of the individual layers of copper ink may be sufficiently thin that the organic elements present in the ink (e.g., the organic solvents and/or other organic binders used to produce a printable/flowable ink) can be removed during the curing process. In some examples, the thickness of individual layers of copper ink is approximately (e.g., ±5% or ±10%) a few micrometers, for example, less than 10 micrometers, in a range of a few nanometers to 10 micrometers, or in a range of 1-10 micrometers. In one example, individual layers of copper ink have a thickness of approximately 5 micrometers.

The printing system 102 may include one or more printing nozzles or jets (e.g., in examples of an aerosol jet printer) used to dispense the copper ink during the printing process. In some examples, the nozzle diameter is selected based on the size, resolution, and/or pitch of the copper structures to be printed. For example, a thinner nozzle may be preferable for printing structures with very fine features and/or pitch between adjacent structures, or where very accurate dimensional tolerances are desired. On the other hand, a wider diameter nozzle may allow for more rapid printing of the structures. In some examples, for an aerosol jet printer, such as the AEROSOL JET 5x system from OPTOMEC, the diameter of the printing nozzle is in a range of about 50 micrometers to 300 micrometers.

Still referring to FIG. 1, as described above, the curing system 104 is used to cure the individual layers of copper ink after they have been deposited by the printing system 102. In some examples, the curing system 104 includes a photonic curing apparatus configured to implement a photonic sintering process to cure the printed layer of copper ink. For example, the curing system 104 may include a photonic sintering system/device. Further, in other examples, a curing process other than photonic sintering can be used. For example, curing can be performed using a laser, such as a near-infrared laser. In some examples, the curing process is one in which non-equilibrium local heating occurs fast enough to cure the copper layer before it oxidizes. This is in contrast to thermal curing processes in which the workpiece is baked in an oven and non-equilibrium heating occurs slowly (e.g., over several minutes or hours). As discussed above, due to the tendency of copper to oxidize quickly, such thermal curing may need to be performed in an inert gas environment. In contrast, in some examples using photonic sintering, the curing process for a thin layer of copper (e.g., having a thickness less than about 10 micrometers) is on the order of a few milliseconds. For example, the photonic sintering process may be applied for a duration in a range of about 1 to 10 milliseconds. Advantageously, the use of photonic sintering allows the curing process to be performed at ambient temperatures and may not require a special environment (e.g., an inert gas environment).

According to certain examples, the photonic sintering process can be tuned for a wide variety of copper inks and conductivities. For example, the energy density of photonic pulses emitted by the curing system 104 can be tuned based on the type of copper ink used and the thickness of the individual printed layers of copper. The energy density of the pulses may be controlled through control of one or more parameters such as the duty cycle of the pulses, the pulse width, and/or the pulse control voltage. In addition, the number of pulses applied during a curing cycle can be adjusted. For example, conductivity of printed copper can be achieved with a pulse control voltage range of 335V to 400V, pulse widths from 5 milliseconds to 8 milliseconds and with a pulse duty cycle of 50%. In such examples, the energy density of the pulses can be in a range of 4.4 Joules per square centimeter (J/cm2) to 6.1 J/cm2.

### Example Methodology

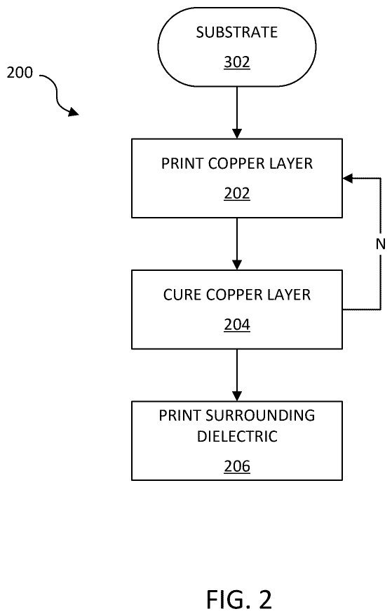

Referring to FIG. 2, there is illustrated a flow diagram of a process 200 for fabricating copper interconnects using additive manufacturing techniques, according to certain examples. The process 200 may be implemented using the system 100 of FIG. 1, for example.

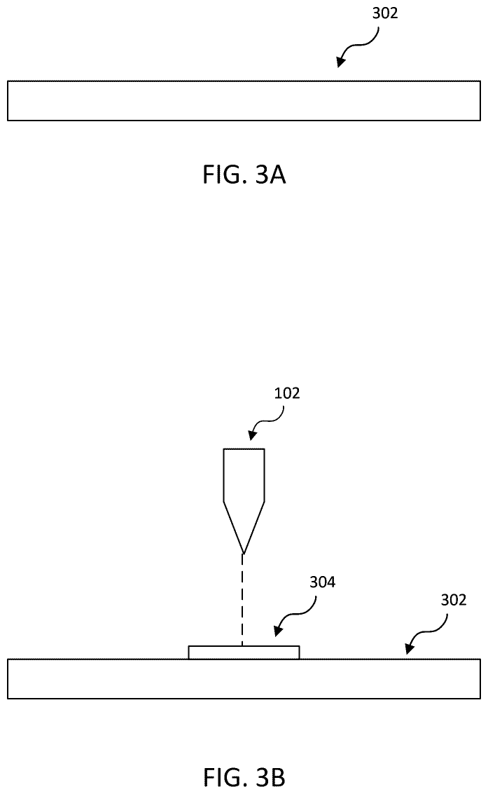

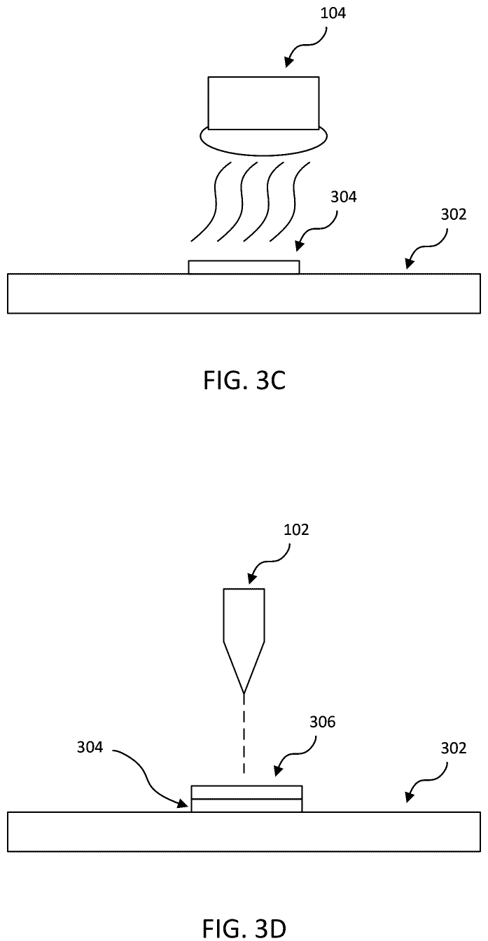

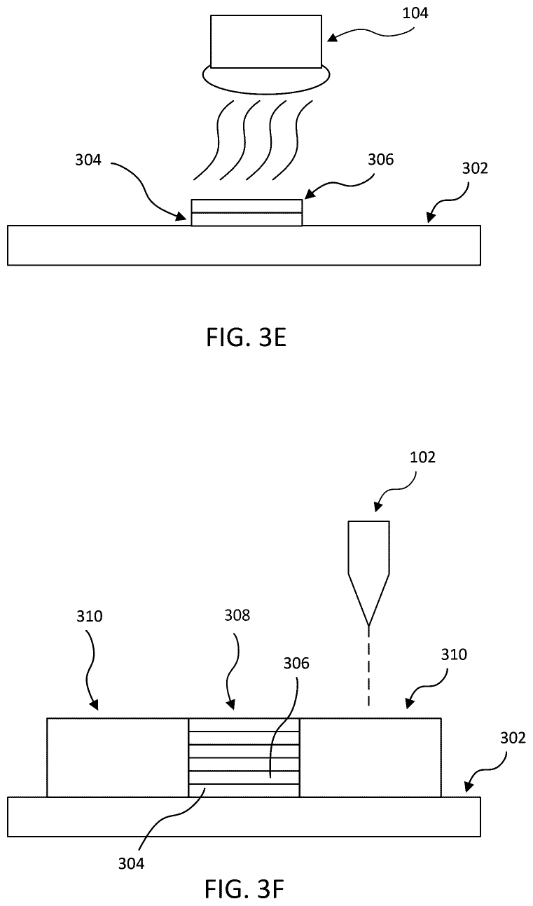

According to certain examples, the process 200 includes forming one or more copper interconnects (e.g., copper pillar structures) on a substrate 302. FIG. 3A illustrates an example of the substrate 302. The substrate 302 may be any type of substrate used for electronic circuits, such as a silicon substrate, a gallium arsenide substrate, or a substate made of other semiconductor material. In some examples, the substrate 302 is a printed circuit board on which a variety of electronic components and/or structures may be populated before, during, and/or after formation of one of more copper interconnects thereon using the process 200.

At operation 202, a layer of copper 304 is printed on the substrate 302 using the printing system 102, as shown in FIG. 3B. As described above, in some examples, the layer of copper 304 is printed on the substrate 302 using a copper ink dispensed by an aerosol jet printer. In some examples, the layer of copper 304 has a thickness in a range of about 1 to 10 micrometers, for example, about 5 micrometers. The layer of copper 304 may have a shape depending on the shape of the overall copper interconnect to be formed. For example, if a cylindrical copper via is to be formed, the layer of copper 304 may have a circular shape on the surface of the substrate 302. In the example shown in FIG. 3B, the layer of copper 304 includes a single portion (e.g., forming part of a single copper interconnect); however, in other examples, the layer of copper 304 may include multiple portions, for example, corresponding to parts of multiple different copper interconnects and/or other copper structures to be formed. In some examples, many copper interconnects, such as several tens, hundreds, or even thousands of copper interconnects, can be formed during one performance of the process 200.

At operation 204, the layer of copper 304 is cured using the curing system 104, as shown in FIG. 3C. As described above, in some examples, the curing system 104 includes a photonic sintering apparatus and in such examples, operation 204 includes photonically sintering the layer of copper 304. In some examples, a photonic sintering process performed at operation 204 may take on the order of a few milliseconds.

Operations 202 and 204 may be repeatedly performed in an alternating manner multiple times (e.g., N times, N being any integer number greater than or equal to 1) to deposit and cure successive layers of copper until the copper interconnect(s) reach a desired height. For example, FIG. 3D illustrates operation 202 being repeated to deposit, using the printing system 102, a second layer of copper 306 on top of the first layer of copper 304. To form a copper pillar, for example, the second layer of copper 306 may have a same shape and thickness as the first layer of copper 304. FIG. 3E illustrates operation 204 being repeated to cure, using the curing system 104, the second layer of copper 306 after it has been printed by the printing system 102, as described above.

At operation 206, once sufficient copper layers have been printed and cured such that the copper interconnect 308 has reached a desired height, the printing system 102 is used to deposit a dielectric material 310 surrounding, or at least partially surrounding, the copper interconnect 308, as shown in FIG. 3F, for example. In some examples, the dielectric material 310 is printed by the printing system 102 using a dielectric ink. In some examples, the dielectric ink is curable using ultraviolet light (e.g., a UV-curable ink). Although not shown in FIG. 2, in some examples, the process 200 may include an additional operation of curing the dielectric material 310 (e.g., by UV curing) after it has been deposited on the substrate 302 at operation 206.

### Example Computing Platform

FIG. 4 illustrates an example computing platform 400 that can be used to implement some components and/or functionality of the system 100 described herein, such as some or all features and/or functionality of the controller 108. In some embodiments, the computing platform 400 may host, or otherwise be incorporated into a personal computer, workstation, server system, laptop computer, ultra-laptop computer, tablet, touchpad, portable computer, handheld computer, palmtop computer, personal digital assistant (PDA), cellular telephone, combination cellular telephone and PDA, smart device (for example, smartphone or smart tablet), mobile internet device (MID), messaging device, data communication device, embedded system, and so forth. Any combination of different devices may be used in certain embodiments. In some embodiments, the computing platform 400 represents one system in a network of systems coupled together via controlled area network (CAN) bus or other network bus.

In some examples, the computing platform 400 may comprise any combination of a processor 402, a memory 404, a network interface 406, an input/output (I/O) system 408, a user interface 410, and a storage system 412. As shown in FIG. 4, a bus and/or interconnect 416 is also provided to allow for communication between the various components listed above and/or other components not shown. The computing platform 400 can be coupled to a network 418 through the network interface 406 to allow for communications with other computing devices, platforms, or resources, including, for example, the printing system 102 and/or the curing system 104. Other componentry and functionality not reflected in the block diagram of FIG. 4 will be apparent in light of this disclosure, and it will be appreciated that other embodiments are not limited to any particular hardware configuration.

The processor 402 can be any suitable processor and may include one or more coprocessors or controllers to assist in control and processing operations associated with the computing platform 400. In some embodiments, the processor 402 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core. In an example, processor 402 can be controller 108, and platform 400 may be communicatively coupled to apparatus 106 via interconnect 416 or network 418.

The memory 404 can be implemented using any suitable type of digital storage including, for example, flash memory and/or random access memory (RAM). In some embodiments, the memory 404 may include various layers of memory hierarchy and/or memory caches as are known to those of skill in the art. The memory 404 may be implemented as a volatile memory device such as, but not limited to, a RAM, dynamic RAM (DRAM), or static RAM (SRAM) device. The storage system 412 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device. In some embodiments, the storage system 412 may comprise technology to increase the storage performance enhanced protection for valuable digital media when multiple hard drives are included.

The processor 402 may be configured to execute an Operating System (OS) 414 which may comprise any suitable operating system, such as Google Android (Google Inc., Mountain View, CA), Microsoft Windows (Microsoft Corp., Redmond, WA), Apple OS X (Apple Inc., Cupertino, CA), Linux, or a real-time operating system (RTOS). As will be appreciated in light of this disclosure, the techniques provided herein can be implemented without regard to the particular operating system provided in conjunction with the computing platform 400, and therefore may also be implemented using any suitable existing or subsequently-developed platform.

The network interface 406 can be any appropriate network chip or chipset which allows for wired and/or wireless connection between other components of the computing platform 400 and/or the network 418, thereby enabling the computing platform 400 to communicate with other local and/or remote computing systems, servers, cloud-based servers, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution), Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

The I/O system 408 may be configured to interface between various I/O devices and other components of the computing platform 400. I/O devices may include, but not be limited to, a user interface 410. The user interface 410 may include devices (not shown) such as a display element, touchpad, keyboard, mouse, and/or speaker, to allow a user to interact with the computing platform 400. For example, the user interface 410 may allow a user to control one or more operating parameters of the printing system 102 and/or the curing system 104.

It will be appreciated that in some embodiments, the various components of the computing platform 400 may be combined or integrated in a system-on-a-chip (SoC) architecture. In some embodiments, the components may be hardware components, firmware components, software components or any suitable combination of hardware, firmware or software.

In various embodiments, the computing platform 400 may be implemented as a wireless system, a wired system, or a combination of both. When implemented as a wireless system, the computing platform 400 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, the computing platform 400 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

The terms “circuit” or “circuitry,” as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, and/or firmware, configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, and/or smart phones. Other embodiments may be implemented as software executed by a programmable control device. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, GPUs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

### Further Example Embodiments

The following examples pertain to further embodiments, from which numerous permutations and configurations will be apparent.
Example 1 is a method comprising printing a layer of copper ink onto a substrate, applying a photonic sintering process to cure the layer of copper ink, iteratively repeating the printing and photonic sintering for a plurality of layers of copper ink, wherein subsequent layers of copper ink are printed overlaying previously printed and cured layers of copper ink, to produce a copper pillar having a selected height, and depositing, onto the substrate, a dielectric material at least partially surrounding the copper pillar.
Example 2 is a method comprising producing a plurality of copper pillars on a substrate by additive manufacturing, individual copper pillars of the plurality of copper pillars including a plurality of stacked layers of copper, each respective layer of copper being photonically sintered prior to a deposition of a subsequent layer of copper stacked on top of the respective layer of copper, and depositing a dielectric material on the substrate at least partially surrounding one or more of the plurality of copper pillars.
Example 3 is a method comprising: printing, using a printable copper ink, a layer of copper onto a substrate; applying a photonic sintering process to cure the layer of copper to produce a cured layer of copper; repeating, in an alternating manner, the printing and the photonic sintering process to individually print and cure a plurality of additional layers of copper over the cured layer of copper to produce a copper pillar having a selected height; and after forming the copper pillar to the selected height, depositing, onto the substrate, a dielectric material at least partially surrounding the copper pillar.
Example 4 includes the method of Example 3, wherein printing the layer of copper is performed using an aerosol jet printer.
Example 5 includes the method of Example 3, wherein depositing the dielectric material comprises printing the dielectric material using the aerosol jet printer.
Example 6 includes the method of any one of Examples 3-5, wherein printing the dielectric material is performed using a dielectric epoxy ink.
Example 7 includes the method of any one of Examples 3-6, wherein the printable copper ink comprises a plurality of copper nanoparticles dispersed in a carrier fluid.
Example 8 includes the method of Example 7, wherein the carrier fluid comprises one or more organic solvents.
Example 9 includes the method of any one of Examples 3-8, wherein applying the photonic sintering process comprises photonically sintering the layer of copper for a duration in a range of 1 to 10 milliseconds.
Example 10 includes the method of any one of Examples 3-9, wherein applying the photonic sintering process comprises applying a plurality of photonic pulses having pulse widths in a range of 5 milliseconds to 8 milliseconds with a pulse duty cycle of 50%.
Example 11 includes the method of Examples 10, wherein applying the photonic sintering process includes controlling a photonic sintering apparatus with a pulse control voltage in a range of 335 volts to 400 volts.
Example 12 includes the method of one of examples 10 or 11, wherein an energy density of the photonic pulses is in a range of 4.4 J/cm2 to 6.1 J/cm2.
Example 13 includes the method of any one of Examples 8-12, wherein printing the layer of copper comprises printing the layer of copper having a thickness in a range of 1 - 10 micrometers.
Example 14 is an apparatus configured to implement the methods of any one of Examples 1-13.
Example 15 is a method comprising: printing, using a printable copper ink, a plurality of layers of copper onto a substrate, individual layers of copper being stacked on top of one another to produce a copper pillar having a selected height; after printing each individual layer of copper, and prior to printing a subsequent layer of copper, curing the individual layer of copper, such that the plurality of layers of copper are individually printed and cured in sequence; and after forming the copper pillar to the selected height, depositing, onto the substrate, a dielectric material at least partially surrounding the copper pillar.
Example 16 includes the method of Example 15, wherein printing the plurality of layers of copper is performed using an aerosol jet printer.
Example 17 includes the method of Example 16, wherein depositing the dielectric material comprises printing a dielectric epoxy ink using the aerosol jet printer.
Example 18 includes the method of any one of Examples 15-17, wherein printing the plurality of layers of copper comprises printing the individual layers of copper each with a thickness of approximately 5 micrometers.
Example 19 includes the method of any one of Examples 15-18, wherein the printable copper ink comprises a plurality of copper nanoparticles dispersed in a carrier fluid.
Example 20 includes the method of Example 19, wherein the carrier fluid comprises one or more organic solvents.
Example 21 includes the method of any one of Examples 15-20, wherein curing the individual layer of copper comprises photonically sintering the individual layer of copper.
Example 22 includes the method of Example 21, wherein photonically sintering the individual layer of copper comprises photonically sintering the individual layer of copper for a duration in a range of 1 to 10 milliseconds.
Example 23 includes the method of one of Examples 21 or 22, wherein photonically sintering the individual layer of copper includes controlling one or more parameters of the photonic sintering apparatus, the one or more parameters including a number of pulses applied to cure the layer of copper, a pulse width of individual pulses applied to cure the layer of copper, a duty cycle of the individual pulses applied to cure the layer of copper, and/or a control voltage applied to generate the pulses applied to cure the layer of copper.
Example 24 includes the method of Example 23, wherein the pulse width is in a range of 5 milliseconds to 8 milliseconds, the duty cycle of the individual pulses is 50%, and/or the control voltage is in a range of 335 volts to 400 volts.
Example 25 includes the method of any one of Examples 15-20, wherein curing the individual layer of copper is performed using a near-infrared laser.
Example 26 is an apparatus configured to implement the method of any one of Examples 15-25.
Example 27 is a computer program product comprising one or more non-transitory machine-readable mediums having instructions encoded thereon that when executed by at least one processor cause a process to be carried out for producing a copper interconnect using additive manufacturing, the process comprising: controlling a printing apparatus to print, using a printable copper ink, a layer of copper onto a substrate; controlling a curing apparatus to cure the layer of copper; repeating, in an alternating manner, the acts of controlling the printing apparatus to print the layer of copper and controlling the curing apparatus to cure the layer of copper to individually print and cure a plurality of additional layers of copper over the layer of copper to produce a copper pillar having a selected height; and after the copper pillar is formed to the selected height, controlling the printing apparatus to print, onto the substrate, a dielectric material at least partially surrounding the copper pillar.
Example 28 includes the computer program product of Example 27, wherein controlling the curing apparatus to cure the layer of copper comprises controlling a photonic sintering apparatus to photonically sinter the layer of copper.
Example 29 includes the computer program product of Example 28, wherein controlling the photonic sintering apparatus comprises controlling the photonic sintering apparatus to sinter the layer of copper for a duration in a range of 1 to 10 milliseconds.
Example 30 includes the computer program product of one of Examples 28 or 29, wherein controlling the photonic sintering apparatus comprises controlling one or more parameters of the photonic sintering apparatus, the one or more parameters including a number of pulses applied to cure the layer of copper, a pulse width of individual pulses applied to cure the layer of copper, a duty cycle of the individual pulses applied to cure the layer of copper, and/or a control voltage applied to generate the pulses applied to cure the layer of copper.
Example 31 includes the computer program product of Example 30, wherein the pulse width is in a range of 5 milliseconds to 8 milliseconds, the duty cycle of the individual pulses is 50%, and/or the control voltage is in a range of 335 volts to 400 volts.
Example 32 includes the computer program product of any one of Examples 27-31, wherein controlling a printing apparatus to print the layer of copper comprises controlling an aerosol jet printer.
Example 33 includes the computer program product of any one of Examples 27-32, wherein controlling the printing apparatus comprises controlling the printing apparatus to print the layer of copper having a thickness in a range of 1 -10 micrometers.
Example 34 includes the computer program product of Example 33, wherein controlling the printing apparatus comprises controlling the printing apparatus to print the layer of copper with a thickness of approximately 5 micrometers.
Example 35 is an apparatus comprising the computer program product of any one of Examples 27-34.
Example 36 is an apparatus for producing a copper interconnect, the apparatus comprising: a printing system configured to print a printable copper; a curing system configured to cure copper printed by the printing system; and a controller configured to cause (a) the printing system to print a layer of copper onto a substrate and (b) the curing system to cure the layer of copper, so as to provide a cured copper layer, cause repeating of (a) and (b) one or more times to produce a copper pillar of a selected height, and after the copper pillar is formed to the selected height, cause the printing system to print a dielectric material at least partially surrounding the copper pillar.
Example 37 includes the apparatus of Example 36, wherein the curing system comprises a photonic sintering system.
Example 38 includes the apparatus of Example 37, wherein the controller is configured to control one or more parameters of the photonic sintering system to cure the layer of copper, the one or more parameters including a number of pulses applied to cure the layer of copper, a pulse width of individual pulses applied to cure the layer of copper, a duty cycle of the individual pulses applied to cure the layer of copper, and/or a control voltage applied to generate the pulses applied to cure the layer of copper.
Example 39 includes the apparatus of one of Examples 37 or 38, wherein the controller is configured to control the photonic sintering system to cure the layer of copper for a duration in a range of 1 - 10 milliseconds.
Example 40 includes the apparatus of any one of Examples 36-39, wherein the printing system comprises an aerosol jet printer.
Example 41 includes the apparatus of any one of Examples 36-40, wherein the printable copper comprises a printable copper ink including a plurality of copper nanoparticles dispersed in a carrier fluid, and wherein the carrier fluid comprises one or more organic solvents.
Example 42 includes the apparatus of any one of Examples 36-41, wherein the controller is configured to control the printing system to print the layer of copper with a thickness of approximately 5 micrometers.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A method comprising:
printing, using a printable copper ink, a layer of copper onto a substrate;
applying a photonic sintering process to cure the layer of copper to produce a cured layer of copper;
repeating, in an alternating manner, the printing and the photonic sintering process to individually print and cure a plurality of additional layers of copper over the cured layer of copper to produce a copper pillar having a selected height; and
after forming the copper pillar to the selected height, depositing, onto the substrate, a dielectric material at least partially surrounding the copper pillar.

2. The method of claim 1, wherein printing the layer of copper is performed using an aerosol jet printer.

3. The method of claim 2, wherein depositing the dielectric material comprises printing the dielectric material using the aerosol jet printer.

4. The method of claim 1, wherein printing the dielectric material is performed using a dielectric epoxy ink.

5. The method of claim 1, wherein the printable copper ink comprises a plurality of copper nanoparticles dispersed in a carrier fluid.

6. The method of claim 5, wherein the carrier fluid comprises one or more organic solvents.

7. The method of claim 1, wherein applying the photonic sintering process comprises photonically sintering the layer of copper for a duration in a range of 1 to 10 milliseconds.

8. The method of claim 1, wherein printing the layer of copper comprises printing the layer of copper having a thickness in a range of 1-10 micrometers.

9. A method comprising:
printing, using a printable copper ink, a plurality of layers of copper onto a substrate, individual layers of copper being stacked on top of one another to produce a copper pillar having a selected height;
after printing each individual layer of copper, and prior to printing a subsequent layer of copper, curing the individual layer of copper, such that the plurality of layers of copper are individually printed and cured in sequence; and
after forming the copper pillar to the selected height, depositing, onto the substrate, a dielectric material at least partially surrounding the copper pillar.

10. The method of claim 9, wherein printing the plurality of layers of copper is performed using an aerosol jet printer.

11. The method of claim 10, wherein depositing the dielectric material comprises printing a dielectric epoxy ink using the aerosol jet printer.

12. The method of claim 9, wherein printing the plurality of layers of copper comprises printing the individual layers of copper each with a thickness of approximately 5 micrometers.

13. The method of claim 9, wherein curing the individual layer of copper comprises photonically sintering the individual layer of copper.

14. The method of claim 13, wherein photonically sintering the individual layer of copper comprises photonically sintering the individual layer of copper for a duration in a range of 1 to 10 milliseconds.

15. The method of claim 9, wherein curing the individual layer of copper is performed using a near-infrared laser.

16. A computer program product comprising one or more non-transitory machine-readable mediums having instructions encoded thereon that when executed by at least one processor cause a process to be carried out for producing a copper interconnect using additive manufacturing, the process comprising:
controlling a printing apparatus to print, using a printable copper ink, a layer of copper onto a substrate;
controlling a curing apparatus to cure the layer of copper;
repeating, in an alternating manner, the acts of controlling the printing apparatus to print the layer of copper and controlling the curing apparatus to cure the layer of copper to individually print and cure a plurality of additional layers of copper over the layer of copper to produce a copper pillar having a selected height; and
after the copper pillar is formed to the selected height, controlling the printing apparatus to print, onto the substrate, a dielectric material at least partially surrounding the copper pillar.

17. The computer program product of claim 16, wherein controlling the curing apparatus to cure the layer of copper comprises controlling a photonic sintering apparatus to photonically sinter the layer of copper.

18. The computer program product of claim 17, wherein controlling the photonic sintering apparatus comprises controlling one or more parameters of the photonic sintering apparatus, the one or more parameters including a number of pulses applied to cure the layer of copper, a pulse width of individual pulses applied to cure the layer of copper, a duty cycle of the individual pulses applied to cure the layer of copper, and/or a control voltage applied to generate the pulses applied to cure the layer of copper.

19. An apparatus for producing a copper interconnect, the apparatus comprising:
a printing system configured to print a printable copper;
a curing system configured to cure copper printed by the printing system; and
a controller configured to
cause (a) the printing system to print a layer of copper onto a substrate and (b) the curing system to cure the layer of copper, so as to provide a cured copper layer,
cause repeating of (a) and (b) one or more times to produce a copper pillar of a selected height, and
after the copper pillar is formed to the selected height, cause the printing system to print a dielectric material at least partially surrounding the copper pillar.

20. The apparatus of claim 19, wherein the curing system comprises a photonic sintering system.

21. The apparatus of claim 20, wherein the controller is configured to control one or more parameters of the photonic sintering system to cure the layer of copper, the one or more parameters including a number of pulses applied to cure the layer of copper, a pulse width of individual pulses applied to cure the layer of copper, a duty cycle of the individual pulses applied to cure the layer of copper, and/or a control voltage applied to generate the pulses applied to cure the layer of copper.

22. The apparatus of claim 19, wherein the printing system comprises an aerosol jet printer.

23. The apparatus of claim 22, wherein the printable copper comprises a printable copper ink including a plurality of copper nanoparticles dispersed in a carrier fluid, and wherein the carrier fluid comprises one or more organic solvents.

24. The apparatus of claim 19, wherein the controller is configured to control the printing system to print the layer of copper with a thickness of approximately 5 micrometers.
